(19) United States
(12) Patent Application Publication
(10) Pub. No.: US 2015/0129870 A1
(43) Pub. Date: May 14, 2015

(54) TFT DRIVING BACKPLANE AND METHOD OF MANUFACTURING THE SAME

(71) Applicant: EverDisplay Optronics (Shanghai) Limited, Shanghai (CN)

(72) Inventors: Lung Pao HSIN, Shanghai (CN); Tien Wang HUANG, Shanghai (CN)

(21) Appl. No.: 14/537,595

(22) Filed: Nov. 10, 2014

(30) Foreign Application Priority Data
Nov. 14, 2013 (CN) 201310567220.8

(51) Int. Cl. H01L 21/428; H01L 29/66; H01L 29/786

(52) U.S. Cl. CPC H01L 21/428; H01L 29/7869; H01L 29/66969; H01L 29/78603; H01L 29/78606
USPC 257/43; 438/104

(57) ABSTRACT

The embodiments of the present disclosure discloses a TFT driving backplane and method of manufacturing the same, which includes the steps of: forming non-transparent gate electrodes on a transparent insulating substrate, blanketing a gate insulating film on the substrate; forming a patterned photoconductive semiconductor layer on the gate insulating film including a superposing region and over-range regions; converting the over-range regions into conductors to be a source region and a drain region; forming a patterned protection layer to cover the photoconductive semiconductor layer and provided with a pixel electrode contacting hole to expose the drain region; forming a pixel electrode coupled with the drain region; and forming an insulating layer covering the protection layer and exposing a part of the pixel electrode. The source region, drain region and channel can be formed in one step by converting photoconductive semiconductor material partially, such that the manufacturing process is simplified.

### CROSS REFERENCE TO RELATED APPLICATIONS

This application claims the priority to and the benefit of Chinese Patent Application No. 201310567220.8, filed Nov. 14, 2013 and entitled “TFT driving backplane and method of manufacturing the same,” which is incorporated herein by reference in its entirety.

### TECHNICAL FIELD

The present disclosure relates generally to the technical field of manufacturing TFT driving backplane, especially to TFT driving backplane and method of manufacturing the same in which the source region, drain region and channel can be formed in one step by converting photoconductive semiconductor material partially.

### BACKGROUND

Nowadays, thin film transistor (TFT) is commonly used to drive subpixels of Liquid Crystal Display (LCD) and Organic Light-Emitting Diode (OLED) display. A driving backplane manufactured based on TFT array is a key member that enables the display to have a higher pixel density, aperture ratio and brightness. The current TFT-LCD commonly adopts TFT backplane having an active layer based on amorphous silicon (a-Si). However, much lower mobility of a-Si makes it unable to meet the requirements for OLED display, high definition TFT-LCD and 3D display. Concerning metal oxide semiconductor used as the active layer material of TFT, it is regarded as the next generation display backplane technology because of the high mobility, low deposition temperature and transparent optical characteristic, which attracts worldwide researcher's attention. The high mobility enables it to meet the requirements for the TFT with high refresh rate and high current in the future display technology. The processing temperature below 100° C. makes it possible to manufacture a flexible display element by metal oxide.

The current TFT driving backplane is divided into two categories which are a-Si TFT driving backplane and polycrystalline silicon (poly-Si) TFT driving backplane.

The method of manufacturing the a-Si TFT driving backplane mainly includes the steps as follows.

Forming a gate electrode and scan lines, which includes steps of sputtering gate electrode metal to form a film, and lithography for the gate electrode metal film.

Forming a gate insulating layer and a-Si island, which includes steps of forming three layers of film in sequence in a manner of plasma enhanced chemical vapor deposition (PECVD), lithography for and dry etching the island and so on, thereafter forming the a-Si island for TFT on a glass substrate.

Forming S/D electrodes, data electrode and channel, which includes steps of sputtering a S/D metal layer to form a film, lithography for and wet etching the S/D, dry etching the channel and so on, finally forming source electrode, drain electrode, channel and data line of TFT on the glass substrate. TFT manufacturing is finished so far.

Forming a passivition layer and via, which includes steps of forming a film in a manner of PECVD, lithography for and dry etching the via and so on. After the above processes, the channel passivition layer and via of TFT are formed on the glass substrate.

Forming an ITO (Indium Tin Oxide)transparent pixel electrode, which includes steps of sputtering ITO transparent electrode layer to form a film, lithography for and wet etching the ITO and so on, thereafter forming transparent pixel electrode on the glass substrate. The whole array process is finished so far.

Low Temperature Poly-Silicon (LTPS) technology is a new generation of manufacturing the TFT-LCD, in which the a-Si film is converted into Poly-Si film layer in a manner of laser anneal. The electron moving speed of Poly-Si transistor is hundreds of times faster than that of a-Si transistor, therefore, the TFT-LCD with Poly-Si transistor has advantageous of quick image response time, high brightness and high resolution etc. In addition, due to fast electron moving speed, Poly-Si is able to be used as driving circuit, such that peripheral driving circuits is allowed to be formed on the glass substrate, thereby reducing weight and meeting requirement of lightness and thinness. Further, in the LTPS TFT, driving IC may be integrated into a LCD panel, thereby lowering IC cost, reducing defective rate during IC later process, and improving qualified rate.

In the prior art, it is required to use 8 masks to manufacture CMOS TFT assemblies of peripheral driving circuits, wherein N-TFTs have lightly doped drain (LDD) structure.

Firstly, depositing a buffer layer and a-Si film layer on an insulating substrate (for example a glass substrate) in turn. The buffer layer plays a function of preventing impurities in the glass substrate from spreading during subsequent high temperature processes. Later, scanning the a-Si film layer with excimer laser (EL) so as to turn a-Si crystals into Poly-Si and then form into a Poly-Si film layer. Then, performing photolithography and etch process to pattern the poly-Si film layer on the glass substrate through a first photoresist pattern (i.e a first photoresist mask is used) so as to form a poly-Si island to be used as N-channel TFT and P-channel TFT, and then depositing a gate insulating layer.

Then, performing a step of N+ ion-implantation of N-TFT to form a second photoresist pattern (i.e a second photoresist mask is used) on the gate insulating layer. The second photoresist pattern covers the LDD structure on the N-TFT, the poly-Si island part on the gate electrode region, and the poly-Si island on the whole P-TFT region. Then, performing a step of N+ ion-implantation to the poly-Si island so as to form an S/D region of N-TFT.

Then, stripping the second photoresist pattern, depositing a gate electrode metal layer, and performing photolithography and etch process to pattern the gate electrode metal layer through a third photoresist pattern (i.e a third photoresist mask is used) so as to form a gate electrode metal of N-TFT and P-TFT. Then, performing a step of ion-implantation with the gate electrode metal as mask directly to form a LDD structure of N-TFT.

Then, forming a fourth photoresist pattern (i.e a fourth photoresist mask is used) to cover the whole N-TFT region, and performing a step of P+ ion-implantation to the P-TFT region to form a S/D region of P-TFT. So far, the main structure of N-TFT and P-TFT is substantially complete.

Afterwards, stripping the fourth photoresist pattern, depositing a dielectric layer on the glass substrate to cover the gate electrode metal, and then performing photolithography and etch process to the dielectric layer and gate insulating layer, and forming a first via hole of N-TFT and P-TFT through a photoresist pattern (i.e a fifth photoresist mask is used) for exposing S/D of N-TFT and P-TFT. Then, depositing a metal layer and filling the first via hole, and then performing photolithography and etch process to the metal layer and forming S/D metal electrode of N-TFT and P-TFT through a photoresist pattern (i.e a sixth photoresist mask is used), which may be used as data line for connecting to a pixel region on the LCD panel and circuit outside of the panel.

Then, depositing a protecting layer on the glass substrate for covering the S/D metal electrode, and performing photolithography and etch process to the protecting layer, and forming a second via hole of N-TFT and P-TFT through a photoresist pattern (i.e a seventh photoresist mask is used) for exposing part of S/D metal electrode. Then, depositing an indium tin oxide (ITO) layer and filling the second via hole, and then performing photolithography and etch process to the ITO layer, and forming ITO connecting electrode through a photoresist pattern (i.e an eighth photoresist mask is used), which may connect to a circuit outside the LCD panel.

It can be seen that the traditional process for manufacturing the driving backplane is complicated, it requires a long period, a considerable amount of metal material and labor, and affects apparatus effectiveness.

### SUMMARY

In order to overcome the above defects in the prior art, the embodiments of the present disclosure provide a TFT driving backplane and method of manufacturing the same, in which problems in the prior art is overcome, the source region, drain region and channel can be formed in one step by converting photoconductive semiconductor material partially, such that the manufacturing processes is simplified, the overall period is shortened, extensive metal material as well as human labor is saved, and apparatus effectiveness is improved.

In one aspect, the present disclosure discloses a thin film transistor (TFT), including: a transparent insulating substrate; a plurality of non-transparent gate electrodes formed on the transparent insulating substrate; a gate insulating film formed on the transparent insulating substrate to cover the gate electrodes; and a patterned photoconductive semiconductor layer formed on the gate insulating film and having a superposing region overlapping the gate electrode and over-range regions integrally formed with the superposing region and exceeding beyond the gate electrode, the over-range regions are converted into conductors respectively to be a source region and a drain region of the TFT.

In an aspect, the over-range regions are converted into conductors by ultraviolet light radiation.

In an aspect, the photoconductive semiconductor layer comprises indium gallium zinc oxide.

In an aspect, the photoconductive semiconductor layer exceeds beyond the gate electrode from two opposite directions.

In an aspect, the transparent insulating substrate is made of glass or flexible dielectric materials.

In an aspect, the present disclosure discloses a method of manufacturing a TFT, including the steps of:

forming a plurality of non-transparent gate electrodes on a transparent insulating substrate;

blanketing a gate insulating film on the transparent insulating substrate to cover the gate electrodes;

forming a patterned photoconductive semiconductor layer on the gate insulating film, wherein the photoconductive semiconductor layer has a superposing region overlapping the gate electrodes and over-range regions integrally formed with the superposing region and exceeding beyond the gate electrodes; and

converting the over-range regions into conductors by electromagnetic radiation respectively to be a source region and a drain region of the TFT.

In an aspect, in the step of converting by electromagnetic radiation, ultraviolet light is provided to penetrate the transparent insulating substrate and only irradiate the over-range regions beyond the gate electrode of the photoconductive semiconductor layer.

In an aspect, the photoconductive semiconductor layer comprises indium gallium zinc oxide.

In an aspect, the photoconductive semiconductor layer exceeds beyond the gate electrode from two opposite directions.

In an aspect, the transparent insulating substrate is made of glass or flexible dielectric materials.

In another aspect, the present disclosure discloses a TFT driving backplane, including: a transparent insulating substrate; a plurality of non-transparent gate electrodes formed on the transparent insulating substrate; a gate insulating film on the transparent insulating substrate to cover the gate electrodes; a patterned photoconductive semiconductor layer formed on the gate insulating film and having a superposing region overlapping the gate electrode and over-range regions integrally formed with the superposing region and exceeding beyond the gate electrode, wherein the over-range regions are converted into conductors respectively to be a source region and a drain region of the TFT; a patterned protection layer covering the photoconductive semiconductor layer and provided with a pixel electrode contacting hole to expose the drain region; a pixel electrode coupled with the drain region via the pixel electrode contacting hole; and an insulating layer formed on the protection layer and exposing a part of the pixel electrode.

In an aspect, the over-range regions are converted into conductors by ultraviolet light radiation.

In an aspect, the photoconductive semiconductor layer comprises indium gallium zinc oxide.

In an aspect, the photoconductive semiconductor layer exceeds beyond the gate electrode from two opposite directions.

In an aspect, the transparent insulating substrate is made of glass or flexible dielectric materials.

In another aspect, the present disclosure discloses a method of manufacturing a TFT driving backplane, including the steps of:

forming a plurality of non-transparent gate electrodes on a transparent insulating substrate;

blanketing a gate insulating film on the transparent insulating substrate to cover the gate electrodes;

forming a patterned photoconductive semiconductor layer on the gate insulating film, wherein the photoconductive semiconductor layer has a superposing region overlapping the gate electrodes and over-range regions integrally formed with the superposing region and exceeding beyond the gate electrodes in a direction of transparent insulating substrate;

converting the over-range regions into conductors by electromagnetic radiation respectively to be a source region and a drain region of the TFT respectively;

forming a patterned protection layer to cover the photoconductive semiconductor layer and provided with a pixel electrode contacting hole to expose the drain region;

forming a pixel electrode coupled with the drain region via the pixel electrode contacting hole; and

forming an insulating layer covering the protection layer and exposing a part of the pixel electrode.

In an aspect, in the step of converting by electromagnetic radiation, ultraviolet light is provided to penetrate the transparent insulating substrate and only irradiate the over-range regions beyond the gate electrode of the photoconductive semiconductor layer.

In an aspect, the photoconductive semiconductor layer comprises indium gallium zinc oxide.

In an aspect, the photoconductive semiconductor layer exceeds beyond the gate electrode from two opposite directions.

In an aspect, the material of the pixel electrode comprises indium-tin oxide.

Compared with the prior art, by the technical solution above, the TFT driving backplane and method of manufacturing the same according to the present disclosure bring the following advantageous effects: the source region, drain region and channel can be formed in one step by converting photoconductive semiconductor material partially, such that the manufacturing process is simplified, without multiple use of the photoresist pattern, thereby reducing the overall period, without requiring extensive metal material, decreasing human labor and improving apparatus effectiveness.

The foregoing summary is not intended to summarize each potential embodiment or every aspect of the present disclosure.

### BRIEF DESCRIPTION OF THE DRAWINGS

FIG. 1 is an illustrative flowchart of manufacturing the TFT according to the first embodiment of the present disclosure;

FIGS. 2A and 2B are schematic views showing structure changes of TFT during manufacture according to the first embodiment of the present disclosure;

FIG. 3 is an illustrative flowchart of manufacturing the TFT driving backplane according to the second embodiment of the present disclosure;

FIG. 4A to FIG. 4E are schematic views showing structure changes of TFT driving backplane during manufacture according to the second embodiment of the present disclosure;

FIG. 5 is an illustrative flowchart of manufacturing a first type of TFT display apparatus according to the third embodiment of the present disclosure;

FIG. 6 illustrates a schematic view of the first type of TFT display apparatus according to the third embodiment of the present disclosure;

FIG. 7 is an illustrative flowchart of manufacturing a second type of TFT display apparatus according to the fourth embodiment of the present disclosure; and

FIG. 8 illustrates a schematic view of the second type of TFT display apparatus according to the fourth embodiment of the present disclosure.

Specific embodiments in this disclosure have been shown by way of example in the foregoing drawings and are hereinafter described in detail. The figures and written description are not intended to limit the scope of the inventive concepts in any manner. Rather, they are provided to illustrate the inventive concepts to a person skilled in the art by reference to particular embodiments.

### DETAILED DESCRIPTION

A skilled person in the art may know that, the embodiment of the disclosure may vary by combining with conventional technology and disclosed embodiments, which is not illustrated herein for concise purpose. Besides, the varied embodiments are not used to affect the concept of the disclosure, which is also not limited herein.

### The First Embodiment

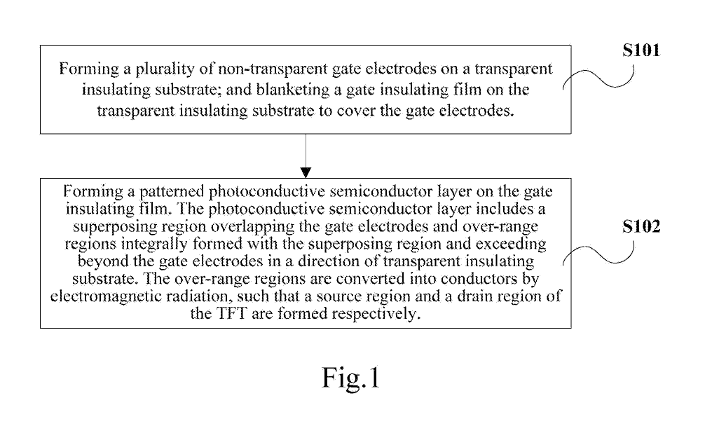

FIG. 1 is an illustrative flowchart of manufacturing the TFT according to the first embodiment of the present disclosure. As shown in FIG. 1, the method of manufacturing the TFT according to the present disclosure includes the steps as follows.

Firstly, in Step S101, forming a plurality of non-transparent gate electrodes on a transparent insulating substrate; and blanketing a gate insulating film on the transparent insulating substrate to cover the gate electrodes.

Then, in Step S102, forming a patterned photoconductive semiconductor layer on the gate insulating film. The photoconductive semiconductor layer includes a superposing region overlapping the gate electrodes and over-range regions integrally formed with the superposing region and exceeding beyond the gate electrodes in a direction of transparent insulating substrate. The over-range regions are converted into conductors by electromagnetic radiation, such that a source region and a drain region of the TFT are formed respectively.

According to the TFT and method of manufacturing the same of the present disclosure, the source region, drain region and channel can be formed in one step by converting photoconductive semiconductor material partially.

The source region and the drain region are formed at two ends of the photoconductive semiconductor layer respectively which acts as the source electrode and drain electrode, thereby omitting steps of forming the source electrode and drain electrode by metal etching, saving material and reducing production process and manufacturing cycle time.

In Step S101, the material of the photoconductive semiconductor layer includes indium gallium zinc oxide. The transparent insulating substrate is made of glass or flexible dielectric materials. The pixel electrode is made of materials including indium-tin oxide.

In Step S102, during conversion performed by electromagnetic radiation, providing a light to penetrate the transparent insulating substrate and only irradiate the over-range regions exceeding beyond the gate electrode of the photoconductive semiconductor layer. The superposing region, shielded and not irradiated by light, is still semiconductor. The light is ultraviolet light. The over-range regions of the photoconductive semiconductor layer exceed beyond the gate electrode from two opposite directions.

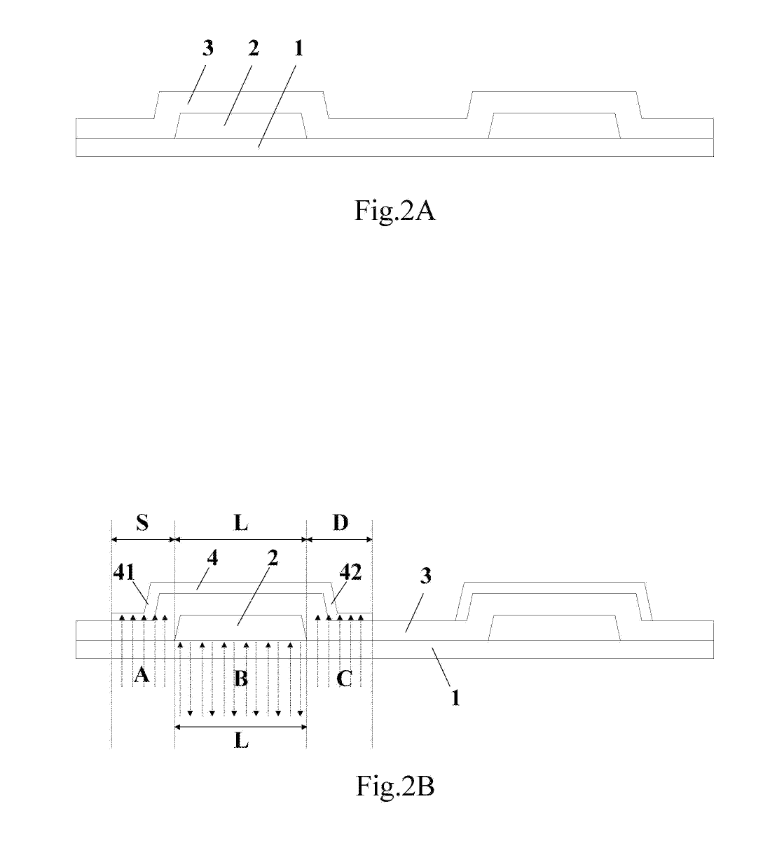

FIGS. 2A and 2B are schematic views showing structure changes of TFT during manufacture according to the first embodiment of the present disclosure.

In Step S101 of FIG. 1, referring to FIG. 2A, the TFT is started from the transparent insulating substrate 1. The transparent insulating substrate may be made of glass or flexible dielectric materials, or any other transparent insulating material which has been known or will be developed in further. The transparent insulating substrate 1 may be, for example, made of transparent flexible dielectric materials. Performing an anneal process at a maximum operatable temperature or around so as to improve dimension stability in subsequent treatment processes.

The non-transparent gate electrode 2 is formed on the surface of the transparent insulating substrate 1 by sputtering. The gate electrode 2 may be made of any conductive material which has been known or will be developed in further. The gate electrode 2 may be made of low-resistance metal. It is possible to adopt traditional photolithography process, such as mask photolithography, to pattern, etch and deposit. During practical manufacture, the transparent insulating substrate 1 can also be formed with gate electrode bus, data line, gate electrode drive circuit, data drive circuit and so on at the surface.

After forming the gate electrode 2 on the surface of the transparent insulating substrate 1, blanketing a gate insulating film 3 on the transparent insulating substrate 1. The gate insulating film 3 may include one of many dielectric materials. The gate insulating film 3 may be formed or deposited with different depths and in manner of any known process. In the present embodiment, the gate insulating film 3 may be made of SiNₓ and deposited in a manner of plasma enhanced chemical vapor deposition (PECVD) so as to fully cover the gate electrode 2.

In Step S102 of FIG. 1, referring to FIG. 2B, after blanketing the gate insulating film 3, forming a patterned photoconductive semiconductor layer 4 on the gate insulating film 3. The photoconductive semiconductor layer 4 may be made of any photoconductive semiconductor material which has been known or will be developed in further. In the present embodiment, the photoconductive semiconductor layer 4 may be indium gallium zinc oxide (IGZO), and formed into film through a sputtering process with target material of In₂O₃: Ga₂O₃: Zn0=1:1:1. The photoconductive semiconductor layer 4 superposes with the gate electrode 2 and exceeds beyond the gate electrode 2 in range. The photoconductive semiconductor layer 4 is shielded by the gate electrode 2 at middle portion, and exceeds beyond the range of the gate electrode 2 at two ends from two directions respectively, thus two ends of the photoconductive semiconductor layer 4 are not shielded by the gate electrode 2.

Many semiconductor materials are sensitive to light, which are not readily conductive without light irradiation, and are readily conductive with light irradiation. For example, the common cadmium sulfide semiconductor photosensitive resistor has a resistance of tens of megohms without light irradiation, and has a resistance reduced to tens of kilo ohms with light irradiation. The phenomena, a semiconductor has a substantial reducing resistance after light irradiation, is referred as “photoconductivity”. IGZO is a kind of photoconductive semiconductor, which is stable in the visible light range, and has a substantially reduced resistance with ultraviolet light irradiation, such that converts into conductor.

Moreover, IGZO is a transparent amorphous oxide semiconductors (TAOS), which has advantage of high mobility, preferable uniformity and transparent, therefore used as the core part of TFT so as to improve the factors which directly affect the performance of TFT devices such as film producing quality, thickness and so on. IGZO film is stable in the visible light range, which has an optical band gap of 3.69 eV close to ultraviolet light range.

Consequently, parallel ultraviolet light passes through the transparent insulating substrate 1 and then irradiates the photoconductive semiconductor layer 4. The superposing region shielded by the gate electrodes 2 is not irradiated by light since the light B is unable to penetrate the gate electrodes 2, therefore, the center portion of the photoconductive semiconductor layer 4 not irradiated by light B is still semiconductor.

The over-range regions at two ends of the photoconductive semiconductor layer 4 which are located beyond the gate electrode 2 are unshielded by the gate electrode 2, and are irradiated by ultraviolet light at Part A and C respectively so as to convert into conductors. The regions where the two ends located are the source region 41 and drain region 42 of TFT. The lengths of regions at two ends of the photoconductive semiconductor layer 4 exceeding beyond the gate electrode are S and D, respectively, i.e., the width of the source region 41 is S, and the width of the drain region 42 is D. The center portion of the photoconductive semiconductor layer 4 is still semiconductor.

Due to utilization of IGZO technology, the present display has power consumption close to that of OLED, much lower cost than that of OLED, a thickness only 25% higher than that of OLED, and a resolution achieving full high definition (HD) even ultra definition (4k*2k) level.

The mobility of IGZO carriers is 20-30 times higher than that of a-Si, which is able to improve charging and discharging rate to pixel electrode by TFT, improve response speed of pixel, thereby reaching a faster refresh rate and greatly increasing line-scan rate of pixel, so as to be able to obtain an ultra high resolution for TFT-LCD. In addition, IGZO display has a higher energy efficiency level and work efficiency due to reduction of quantity of TFT and increment of light transmittance of each pixel.

In the present disclosure, the channel of the photoconductive semiconductor layer 4 having a length of L is directly formed by controlling the gate electrodes 2 having a width of L. Since light is blocked at Part B of the gate electrodes 2, a semiconductor region having a width of L equal to that of Part B is retained at the photoconductive semiconductor layer 4, which is used as channel. Therefore, the channel also has a width of L. The above manner has advantageous of improving aperture ratio easily and effectively and increasing brightness of TFT. Similarly, the lengths of the source region 41 and drain region 42 can be effectively formed by controlling the lengths S and D of regions at two ends of the photoconductive semiconductor layer 4 exceeding beyond the gate electrodes 2 respectively according to specific process requirements.

With continuing reference to FIG. 2B, the TFT according to the present disclosure includes a transparent insulating substrate 1, a plurality of non-transparent gate electrodes 2, a gate insulating film 3, a patterned photoconductive semiconductor layer 4, a patterned protection layer, a plurality of pixel electrodes 6 and an insulating layer 7.

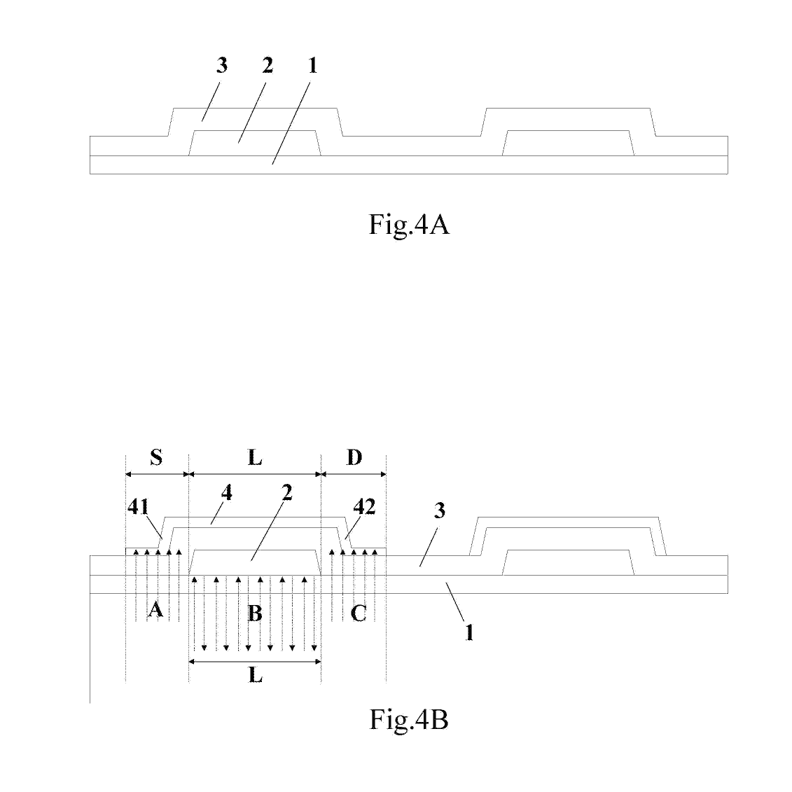

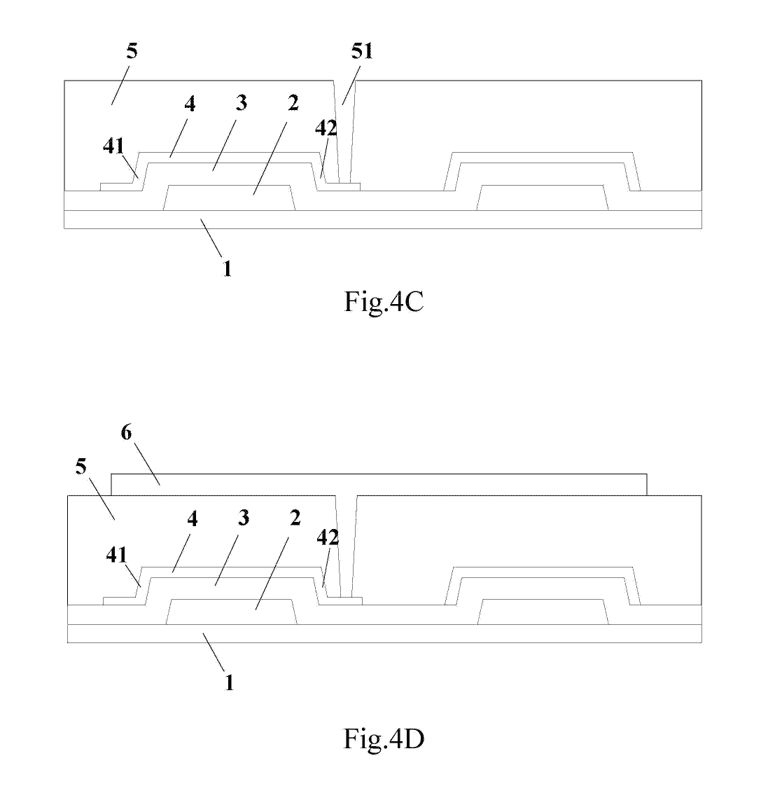

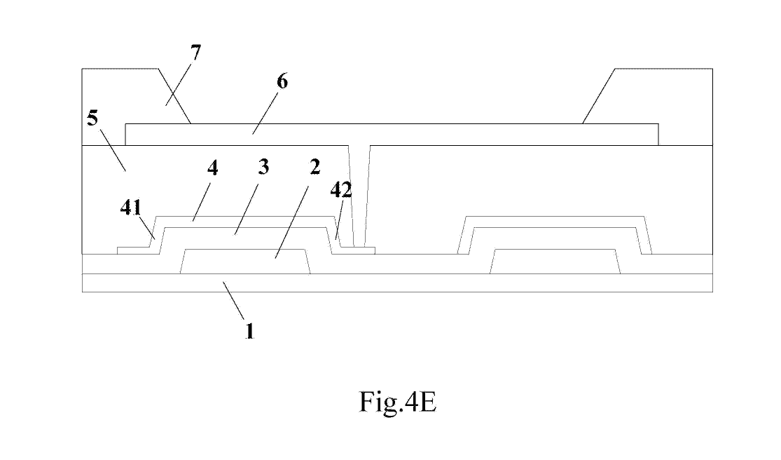

The gate electrodes 2 are formed on the transparent insulating substrate 1. The gate insulating film 3 is formed on the transparent insulating substrate 1 to cover the gate electrodes 2. The patterned photoconductive semiconductor layer 4 is formed on the gate insulating film 3 with regions overlapping the gate electrodes 2 and regions exceeding beyond the gate electrodes 2. The over-range regions exceeding beyond the gate electrodes 2 are converted into conductors by electromagnetic radiation, such that a source region 41 and a drain region 42 of the TFT are formed respectively. The protection layer covers the photoconductive semiconductor layer 4 and is provided with a pixel electrode contacting hole 51 (referring to FIG. 4C) to expose the drain region 42. The pixel electrode 6 is coupled with the drain region 42 via the pixel electrode contacting hole 51. The insulating layer 7 is formed on the protection layer and exposes a part of the pixel electrode 6.

The transparent insulating substrate 1 is made of glass or flexible dielectric materials. The material of the photoconductive semiconductor layer 4 includes indium gallium zinc oxide. The material of the pixel electrode includes indium-tin oxide. The regions of the photoconductive semiconductor layer 4 exceed beyond the gate electrode 2 from two opposite directions, which are irradiated by light to convert into conductors. The region of the photoconductive semiconductor layer 4 overlapping the gate electrodes 2 is shielded and not subjected to irradiate, thereby being still semiconductor. The light is ultraviolet light.

### The Second Embodiment

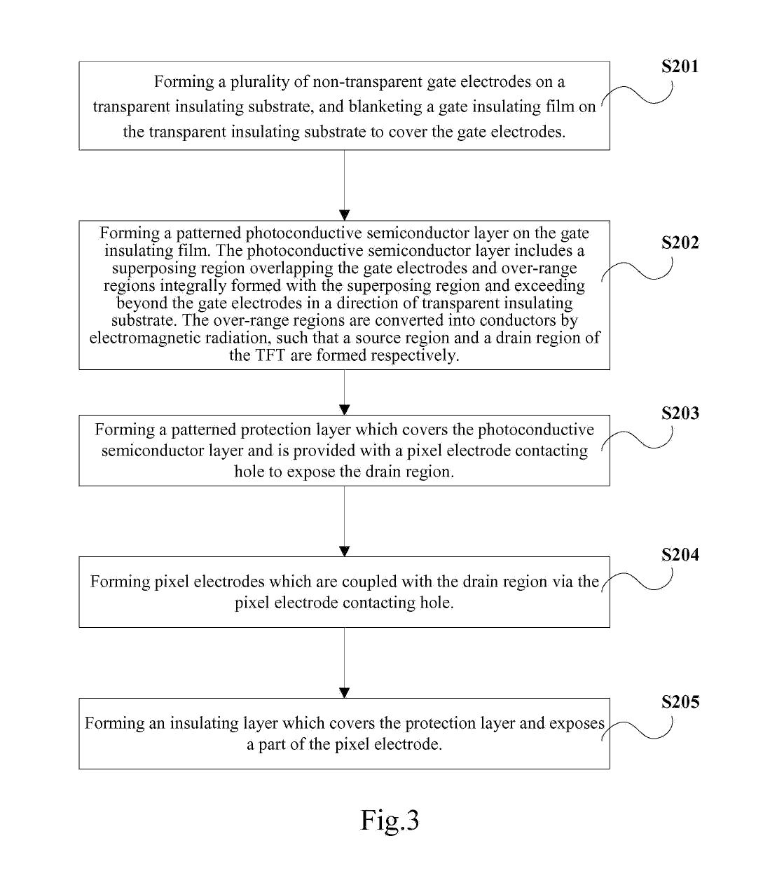

FIG. 3 is an illustrative flowchart of manufacturing the TFT driving backplane according to the second embodiment of the present disclosure. As shown in FIG. 3, the method of manufacturing the TFT driving backplane according to the present disclosure includes the steps as follows.

Firstly, Step S201: forming a plurality of non-transparent gate electrodes on a transparent insulating substrate, and blanketing a gate insulating film on the transparent insulating substrate to cover the gate electrodes.

Then, Step S202: forming a patterned photoconductive semiconductor layer on the gate insulating film. The photoconductive semiconductor layer includes a superposing region overlapping the gate electrodes and over-range regions integrally formed with the superposing region and exceeding beyond the gate electrodes in a direction of transparent insulating substrate. The over-range regions are converted into conductors by electromagnetic radiation, such that a source region and a drain region of the TFT are formed respectively.

Next, Step S203: forming a patterned protection layer which covers the photoconductive semiconductor layer and is provided with a pixel electrode contacting hole to expose the drain region.

Then, Step S204: forming pixel electrodes which are coupled with the drain region via the pixel electrode contacting hole.

Finally, Step S205: forming an insulating layer which covers the protection layer and exposes a part of the pixel electrode.

According to the TFT driving backplane and method of manufacturing the same of the present disclosure, the source region, drain region and channel can be formed in one step by converting photoconductive semiconductor material partially.

The source region and a drain region are formed at two ends of the photoconductive semiconductor layer respectively, they act as the source electrode and drain electrode, thereby omitting steps of metal etching the source electrode and drain electrode, saving material and reducing production processes and manufacturing cycle time.

In Step S201, the material of the photoconductive semiconductor layer includes indium, gallium, and zinc oxide. The transparent insulating substrate is made of glass or flexible dielectric materials. The pixel electrode is made of materials including indium-tin oxide.

In Step S202, during conversion performed by electromagnetic radiation, providing a light to penetrate the transparent insulating substrate and only irradiate the over-range regions exceeding beyond the gate electrode of the photoconductive semiconductor layer. The superposing region, shielded and not irradiated by light, is still semiconductor. The light is ultraviolet light. The over-range regions of the photoconductive semiconductor layer are located beyond the gate electrode from two opposite directions.

FIG. 4A to 4B are schematic views showing structure changes of TFT driving backplane during manufacture according to the second embodiment of the present disclosure;

In Step S201 of FIG. 3, referring to FIG. 4A, the initial material of TFT driving backplane is the transparent insulating substrate 1. The transparent insulating substrate may be made of glass or flexible dielectric materials, or any other transparent insulating material which has been known or will be developed in further. The transparent insulating substrate 1 may be, for example, made of transparent flexible dielectric materials. Performing an anneal process at a maximum operatable temperature or around so as to improve dimension stability in subsequent treatment processes.

The non-transparent gate electrode 2 is formed on the surface of the transparent insulating substrate 1 by sputtering. The gate electrode 2 may be made of any conductive material which has been known or will be developed in further. The gate electrode 2 may be made of low-resistance metal. It is possible to adopt traditional photolithography process, such as mask photolithography, to pattern, etch and deposit. During practical manufacture, the transparent insulating substrate 1 can also be formed with gate electrode bus, data line, gate electrode drive circuit, data drive circuit and so on at the surface.

After forming the gate electrode 2 on the surface of the transparent insulating substrate 1, blanketing a gate insulating film 3 on the transparent insulating substrate 1. The gate insulating film 3 may include one of many dielectric materials. The gate insulating film 3 may be formed (or deposited) with different thicknesses and in manner of any known process. In the present embodiment, the gate insulating film 3 is made of SiNₓ and deposited in a manner of plasma enhanced chemical vapor deposition (PECVD) so as to totally cover the gate electrode 2.

In Step S202 of FIG. 3, referring to FIG. 4B, after blanketing the gate insulating film 3, forming a patterned photoconductive semiconductor layer 4 on the gate insulating film 3. The photoconductive semiconductor layer 4 may be made of any photoconductive semiconductor material which has been known or will be developed in further. In the present embodiment, the photoconductive semiconductor layer 4 may be indium gallium zinc oxide (IGZO), and formed into film through a sputtering process with target material of In₂O₃: Ga₂O₃: Zn0=1:1:1. The photoconductive semiconductor layer 4 superposes with the gate electrode 2 and exceeds beyond the gate electrode 2 in range. The photoconductive semiconductor layer 4 is shielded by the gate electrode 2 at middle portion, and exceeds beyond the range of the gate electrode 2 at two ends from two directions respectively, thus two ends of the photoconductive semiconductor layer 4 are not shielded by the gate electrode 2.

In the present disclosure, the channel of the photoconductive semiconductor layer 4 having a length of L is directly formed by controlling the gate electrodes 2 having a width of L. Since light is blocked at Part B of the gate electrodes 2, a semiconductor region having a width of L equal to that of Part B is retained at the photoconductive semiconductor layer 4, which is used as channel. Therefore, the channel also has a width of L. The above manner has advantageous of improving aperture ratio and increasing brightness of TFT driving backplane. Similarly, the source region 41 and drain region 42 can be effectively formed by controlling the lengths S and D of regions at two ends of the photoconductive semiconductor layer 4 exceeding beyond the gate electrodes 2 respectively according to specific process requirements.

In Step S203 of FIG. 3, referring to FIG. 4C, after forming the source region 41 and drain region 42 on the photoconductive semiconductor layer 4, forming a patterned protection layer 5. The protection layer 5 extends on the gate insulating film 3 and photoconductive semiconductor layer 4. The protection layer 5 is deposited in a manner of PECVD. The protection layer 5 may include one of many dielectric materials and formed (or deposited) with different thicknesses. The protection layer 5 may also be formed in any manner of deposition process which has been known or will be developed in future or photolithography process. In the present embodiment, the protection layer 5 is made of SiNₓ. In addition, the pattern of the protection layer 5 includes pixel electrode contacting hole 51 located above the drain region 42 of the photoconductive semiconductor layer 4 to expose the drain region 42.

In Step S204 of FIG. 3, referring to FIG. 4D, after forming the protection layer 5, forming the pixel electrode 6. The pixel electrode 6 is injected into the pixel electrode contacting hole 51, and coupled with the drain region 42. The pixel electrode 6 may include one of many transparent conductive materials and formed (or deposited) with different thicknesses. The pixel electrode 6 may be formed in any manner of deposition process which has been known or will be developed in further or photolithography process. In the present embodiment, the pixel electrode 6 is made of Indium Tin Oxide (ITO) or Sn-doped In₂O₃. ITO has characteristic of electrical conductivity and optical transparency. However, the characteristic needs to be compromised during film deposition, since charge carriers with high concentration increases the electrical conductivity while reduces transparency. ITO film is commonly formed on the surface in manner of physical vapor deposition or sputtering deposition. ITO is a mixture of In₂O₃ and SnO₂ with the mass ratios 9:1 (that is, ITO is generally formed by 90% In₂O₃ and 10% SnO₂ by mass). ITO film is a heavily doped and heavily degenerated n-type semiconductor material, it has a forbidden band gap close to 3 eV, high electrical conductivity, high visible ray permeability, high mechanical hardness and great chemical stability.

In Step S205 of FIG. 3, referring to FIG. 4E, after forming the pixel electrode 6, forming an insulating layer 7 to cover the protection layer 5 and exposing parts of pixel electrode 6. The insulating layer 7 may include one of many dielectric materials and may be formed (or deposited) with different thicknesses.

With continuing reference to FIG. 4E, the TFT driving backplane according to the present disclosure includes a transparent insulating substrate 1, a plurality of non-transparent gate electrodes 2, a gate insulating film 3, a patterned photoconductive semiconductor layer 4, a patterned protection layer, a plurality of pixel electrodes 6 and an insulating layer 7.

The gate electrodes 2 are formed on the transparent insulating substrate 1. The gate insulating film 3 is formed on the transparent insulating substrate 1 to cover the gate electrodes 2. The patterned photoconductive semiconductor layer 4 is formed on the gate insulating film 3 with regions overlapping the gate electrodes 2 and regions exceeding beyond the gate electrodes 2. The over-range regions exceeding beyond the gate electrodes 2 are converted into conductors by electromagnetic radiation, such that a source region 41 and a drain region 42 of the TFT are formed respectively. The protection layer covers the photoconductive semiconductor layer 4 and is provided with a pixel electrode contacting hole 51 to expose the drain region 42. The pixel electrode 6 is coupled with the drain region 42 via the pixel electrode contacting hole 51. The insulating layer 7 is formed on the protection layer and exposes a part of the pixel electrode 6.

The transparent insulating substrate 1 is made of glass or flexible dielectric materials. The photoconductive semiconductor layer 4 is made of materials including indium, gallium, and zinc oxide. The pixel electrode 6 is made of materials including indium-tin oxide. The regions of the photoconductive semiconductor layer 4 exceed beyond the gate electrode 2 from two opposite directions, which are irradiated by light to convert into conductors. The region of the photoconductive semiconductor layer 4 overlapping the gate electrodes 2 is shielded and not subjected to irradiate, thereby being still semiconductor. The light is ultraviolet light.

### The Third Embodiment

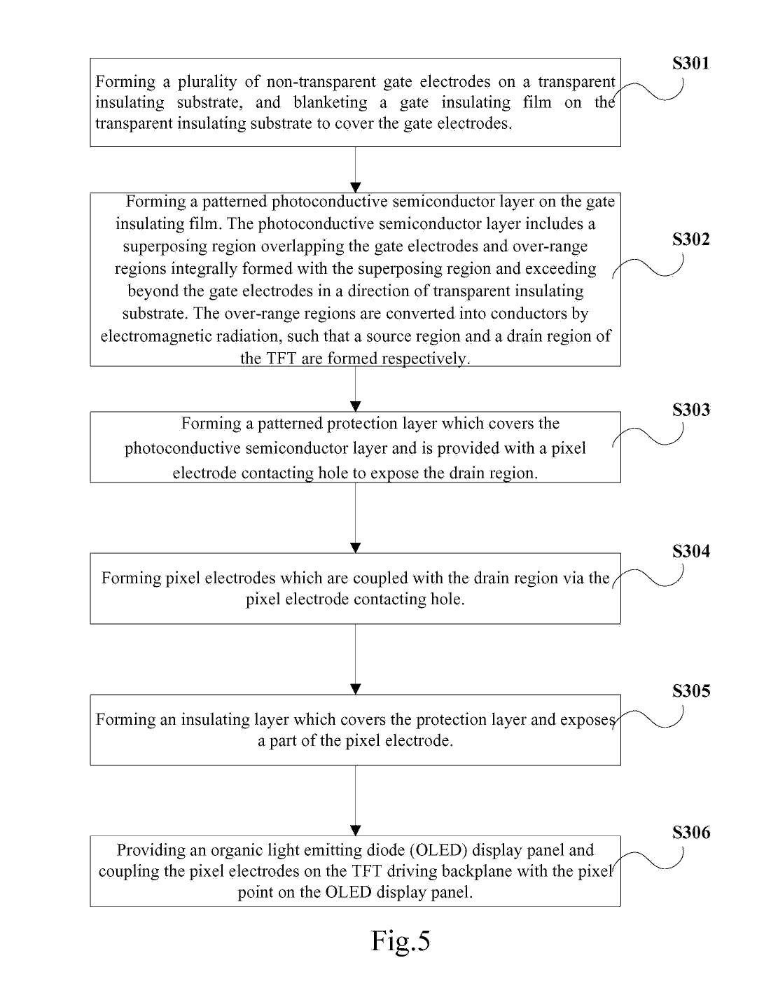

FIG. 5 is an illustrative flowchart of manufacturing a first type of TFT display apparatus according to the third embodiment of the present disclosure. As shown in FIG. 5, the method of manufacturing the first type of TFT display apparatus according to the present disclosure includes the steps as follows.

Firstly, Step S301: forming a plurality of non-transparent gate electrodes on a transparent insulating substrate, and blanketing a gate insulating film on the transparent insulating substrate to cover the gate electrodes.

Then, Step S302: forming a patterned photoconductive semiconductor layer on the gate insulating film. The photoconductive semiconductor layer includes a superposing region overlapping the gate electrodes and over-range regions integrally formed with the superposing region and exceeding beyond the gate electrodes in a direction of transparent insulating substrate. The over-range regions are converted into conductors by electromagnetic radiation, such that a source region and a drain region of the TFT are formed respectively.

Next, Step S303: forming a patterned protection layer which covers the photoconductive semiconductor layer and is provided with a pixel electrode contacting hole to expose the drain region.

Then, Step S304: forming pixel electrodes which are coupled with the drain region via the pixel electrode contacting hole.

Next, Step S305: forming an insulating layer which covers the protection layer and exposes a part of the pixel electrode.

Finally, Step S306: providing an organic light emitting diode (OLED) display panel and coupling the pixel electrodes on the TFT driving backplane with the pixel point on the OLED display panel.

The steps from S301 to S305 are the same as steps from S201 to S205 and the detailed description is omitted herein.

In Step S306, the TFT driving backplane formed by the method according to the present disclosure is coupled with OLED display panel, the OLED display panel may be a common one or anyone developed in further.

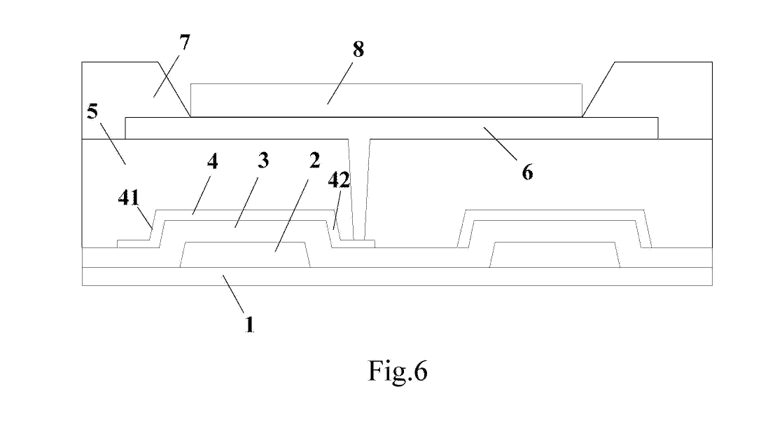

FIG. 6 illustrates a schematic view of the first type of TFT display apparatus according to the third embodiment of the present disclosure. As shown in FIG. 6, the first TFT display apparatus according to the present disclosure includes a transparent insulating substrate 1, a plurality of non-transparent gate electrodes 2, a gate insulating film 3, a patterned photoconductive semiconductor layer 4, a patterned protection layer, a plurality of pixel electrodes 6, an insulating layer 7 and a pixel point 8 of the OLED display panel.

The gate electrodes 2 are formed on the transparent insulating substrate 1. The gate insulating film 3 is formed on the transparent insulating substrate 1 to cover the gate electrodes 2. The patterned photoconductive semiconductor layer 4 is formed on the gate insulating film 3 with regions overlapping the gate electrodes 2 and regions exceeding beyond the gate electrodes 2. The over-range regions exceeding beyond the gate electrodes 2 are converted into conductors by electromagnetic radiation, such that a source region 41 and a drain region 42 of the TFT are formed respectively. The protection layer covers the photoconductive semiconductor layer 4 and is provided with a pixel electrode contacting hole (see reference number 51 in FIG. 4C) to expose the drain region 42. The pixel electrode 6 is coupled with the drain region 42 via the pixel electrode contacting hole. The insulating layer 7 is formed on the protection layer and exposes a part of the pixel electrode 6. The pixel electrodes 6 on the TFT driving backplane are coupled with the pixel point 8 of the OLED display panel.

The transparent insulating substrate 1 is made of glass or flexible dielectric materials. The material of the photoconductive semiconductor layer 4 includes indium gallium zinc oxide. The material of the pixel electrode includes indium-tin oxide. The regions of the photoconductive semiconductor layer 4 exceed beyond the gate electrode 2 from two opposite directions, which are irradiated by light to convert into conductors. The region of the photoconductive semiconductor layer 4 overlapping the gate electrodes 2 is shielded and not subjected to irradiate, thereby being still semiconductor. The light is ultraviolet light.

The TFT driving backplane formed by the method according to the present disclosure is able to be maximized coupled with the OLED display panel so as to form a display apparatus.

### The Fourth Embodiment

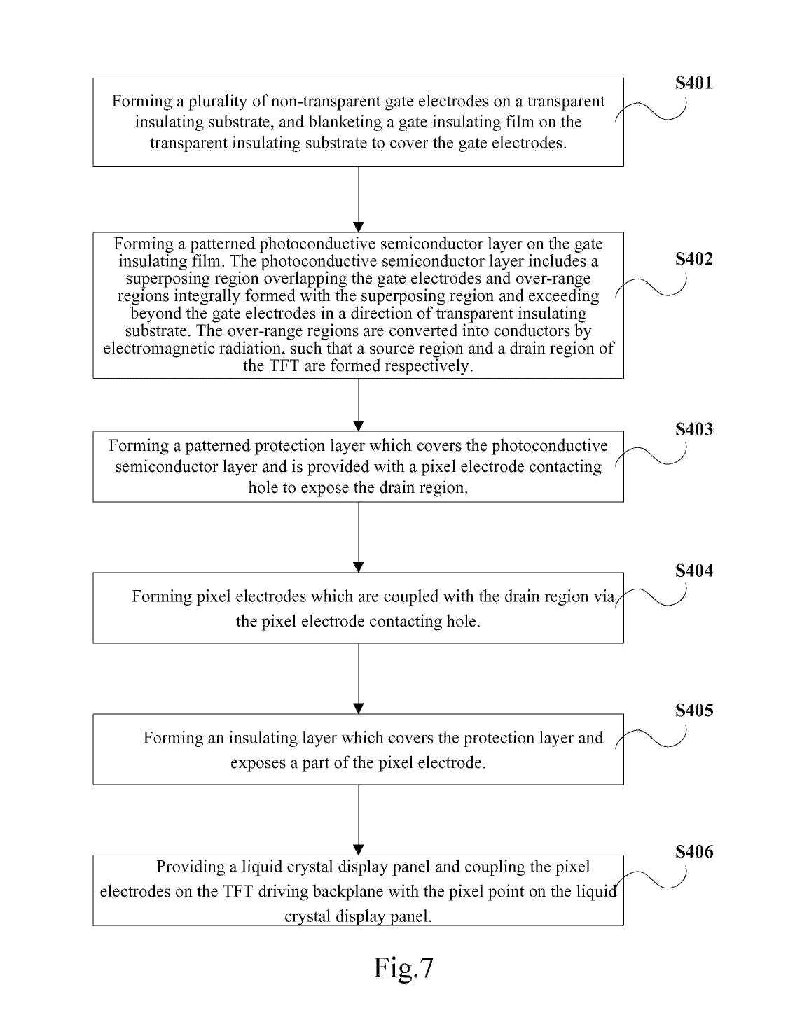

FIG. 7 is an illustrative flowchart of manufacturing a second type of TFT display apparatus according to the fourth embodiment of the present disclosure. As shown in FIG. 7, the method of manufacturing the second type of TFT display apparatus according to the present disclosure includes the steps as follows.

Firstly, Step S401: forming a plurality of non-transparent gate electrodes on a transparent insulating substrate, and blanketing a gate insulating film on the transparent insulating substrate to cover the gate electrodes.

Then, Step S402: forming a patterned photoconductive semiconductor layer on the gate insulating film. The photoconductive semiconductor layer includes a superposing region overlapping the gate electrodes and over-range regions integrally formed with the superposing region and exceeding beyond the gate electrodes in a direction of transparent insulating substrate. The over-range regions are converted into conductors by electromagnetic radiation, such that a source region and a drain region of the TFT are formed respectively.

Next, Step S403: forming a patterned protection layer which covers the photoconductive semiconductor layer and is provided with a pixel electrode contacting hole to expose the drain region.

Then, Step S404: forming pixel electrodes which are coupled with the drain region via the pixel electrode contacting hole.

Next, Step S405: forming an insulating layer which covers the protection layer and exposes a part of the pixel electrode.

Finally, Step S406: providing a liquid crystal display panel and coupling the pixel electrodes on the TFT driving backplane with the pixel point on the liquid crystal display panel.

The steps from S401 to S405 are the same as steps from S201 to S205 and the detailed description is omitted herein.

In Step S406, the TFT driving backplane formed by the method according to the present disclosure is coupled with liquid crystal display panel, the liquid crystal display panel may be a common one or anyone developed in further.

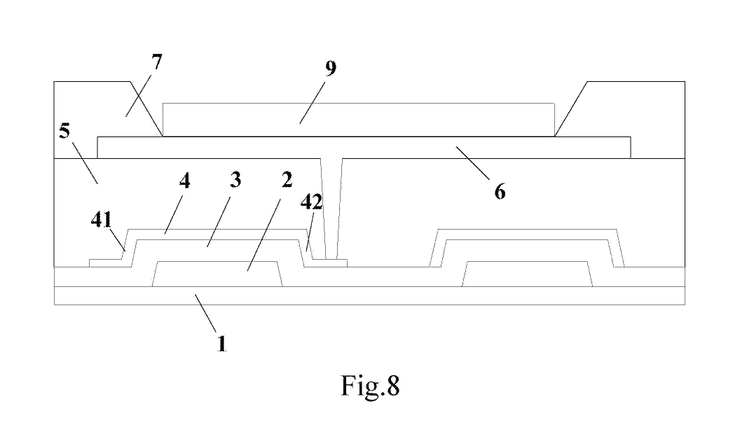

FIG. 8 illustrates a schematic view of the second type of TFT display apparatus according to the fourth embodiment of the present disclosure. As shown in FIG. 8, the second TFT display apparatus according to the present disclosure includes a transparent insulating substrate 1, a plurality of non-transparent gate electrodes 2, a gate insulating film 3, a patterned photoconductive semiconductor layer 4, a patterned protection layer, a plurality of pixel electrodes 6, an insulating layer 7 and a pixel point 9 of the liquid crystal display panel.

The gate electrodes 2 are formed on the transparent insulating substrate 1. The gate insulating film 3 is formed on the transparent insulating substrate 1 to cover the gate electrodes 2. The patterned photoconductive semiconductor layer 4 is formed on the gate insulating film 3 with regions overlapping the gate electrodes 2 and regions exceeding beyond the gate electrodes 2. The over-range regions exceeding beyond the gate electrodes 2 are converted into conductors by electromagnetic radiation, such that a source region 41 and a drain region 42 of the TFT are formed respectively. The protection layer covers the photoconductive semiconductor layer 4 and is provided with a pixel electrode contacting hole (see reference number 51 in FIG. 4C) to expose the drain region 42. The pixel electrode 6 is coupled with the drain region 42 via the pixel electrode contacting hole. The insulating layer 7 is formed on the protection layer and exposes a part of the pixel electrode 6. The pixel electrodes 6 on the TFT driving backplane are coupled with the pixel point 9 of the liquid crystal display panel.

The transparent insulating substrate 1 is made of glass or flexible dielectric materials. The material of the photoconductive semiconductor layer 4 includes indium gallium zinc oxide. The material of the pixel electrode includes indium-tin oxide. The regions of the photoconductive semiconductor layer 4 exceed beyond the gate electrode 2 from two opposite directions, which are irradiated by light to convert into conductors. The region of the photoconductive semiconductor layer 4 overlapping the gate electrodes 2 is shielded and not subjected to irradiate, thereby being still semiconductor. The light is ultraviolet light.

The TFT driving backplane formed by the method according to the present disclosure is able to be maximized coupled with the liquid crystal display panel so as to form a display apparatus.

In conclusion, according to the TFT driving backplane and method of manufacturing the same of the present disclosure, the source region, drain region and channel can be formed in one step by converting photoconductive semiconductor material partially, such that the manufacturing process is simplified, without multiple use of the photoresist pattern, thereby reducing the overall period, without requiring extensive metal material, decreasing human labor and improving apparatus effectiveness.

It should be noted that the above embodiments are only illustrated for describing the technical solution of the disclosure and not restrictive, and although the embodiments are described in detail by referring to the aforesaid embodiments, the skilled in the art should understand that the aforesaid embodiments can be modified and portions of the technical features therein may be equally changed, which does not depart from the spirit and scope of the technical solution of the embodiments of the disclosure.

What is claimed is:

1. A thin film transistor (TFT) comprising:
a transparent insulating substrate;
a plurality of non-transparent gate electrodes formed on the transparent insulating substrate;
a gate insulating film formed on the transparent insulating substrate to cover the gate electrodes; and
a patterned photoconductive semiconductor layer formed on the gate insulating film and having a superposing region overlapping the gate electrode and over-range regions integrally formed with the superposing region and exceeding beyond the gate electrode, wherein the over-range regions are converted into conductors respectively to be a source region and a drain region of the TFT.

2. The TFT according to claim 1, wherein the over-range regions are converted into conductors by ultraviolet light radiation.

3. The TFT according to claim 1, wherein the photoconductive semiconductor layer comprises indium gallium zinc oxide.

4. The TFT according to claim 1, wherein the photoconductive semiconductor layer exceeds beyond the gate electrode from two opposite directions.

5. The TFT according to claim 1, wherein the transparent insulating substrate is made of glass or flexible dielectric materials.

6. A method of manufacturing a TFT comprising the steps of:
forming a plurality of non-transparent gate electrodes on a transparent insulating substrate;
blanketing a gate insulating film on the transparent insulating substrate to cover the gate electrodes;
forming a patterned photoconductive semiconductor layer on the gate insulating film, wherein the photoconductive semiconductor layer has a superposing region overlapping the gate electrodes and over-range regions integrally formed with the superposing region and exceeding beyond the gate electrodes; and
converting the over-range regions into conductors by electromagnetic radiation respectively to be a source region and a drain region of the TFT.

7. The method of manufacturing a TFT according to claim 6, wherein ultraviolet light is provided to penetrate the transparent insulating substrate to irradiate the over-range regions.

8. The method of manufacturing a TFT according to claim 6, wherein the photoconductive semiconductor layer comprises indium gallium zinc oxide.

9. The method of manufacturing a TFT according to claim 6, wherein the photoconductive semiconductor layer exceeds beyond the gate electrode from two opposite directions.

10. The method of manufacturing a TFT according to claim 6, wherein the transparent insulating substrate is made of glass or flexible dielectric materials.

11. A TFT driving backplane comprising:
a transparent insulating substrate;
a plurality of non-transparent gate electrodes formed on the transparent insulating substrate;
a gate insulating film formed on the transparent insulating substrate to cover the gate electrodes;
a patterned photoconductive semiconductor layer formed on the gate insulating film and having a superposing region overlapping the gate electrode and over-range regions integrally formed with the superposing region and exceeding beyond the gate electrode, wherein the over-range regions are converted into conductors respectively to be a source region and a drain region of the TFT;
a patterned protection layer covering the photoconductive semiconductor layer and provided with a pixel electrode contacting hole to expose the drain region;
a pixel electrode coupled with the drain region via the pixel electrode contacting hole; and
an insulating layer formed on the protection layer and exposing a part of the pixel electrode.

12. The TFT driving backplane according to claim 11, wherein the over-range regions are converted into conductors by ultraviolet light radiation.

13. The TFT driving backplane according to claim 11, wherein the photoconductive semiconductor layer comprises indium gallium zinc oxide.

14. The TFT driving backplane according to claim 11, wherein the photoconductive semiconductor layer exceeds beyond the gate electrode from two opposite directions.

15. The TFT driving backplane according to claim 11, wherein the material of the pixel electrode comprises indium-tin oxide.

16. A method of manufacturing a TFT driving backplane comprising the steps of:
forming a plurality of non-transparent gate electrodes on a transparent insulating substrate;
blanketing a gate insulating film on the transparent insulating substrate to cover the gate electrodes;
forming a patterned photoconductive semiconductor layer on the gate insulating film, wherein the photoconductive semiconductor layer has a superposing region overlapping the gate electrodes and over-range regions integrally formed with the superposing region and exceeding beyond the gate electrodes;
converting the over-range regions into conductors by electromagnetic radiation respectively to be a source region and a drain region of the TFT;
forming a patterned protection layer to cover the photoconductive semiconductor layer and provided with a pixel electrode contacting hole to expose the drain region;
forming a pixel electrode coupled with the drain region via the pixel electrode contacting hole; and
forming an insulating layer covering the protection layer and exposing a part of the pixel electrode.

17. The method of manufacturing a TFT driving backplane according to claim 16, wherein in the step of converting by electromagnetic radiation, ultraviolet light is provided to penetrate the transparent insulating substrate and only irradiate the over-range regions exceeding beyond the gate electrode of the photoconductive semiconductor layer.

18. The method of manufacturing a TFT driving backplane according to claim 16, wherein the photoconductive semiconductor layer comprises indium gallium zinc oxide.

19. The method of manufacturing a TFT driving backplane according to claim 16, wherein the photoconductive semiconductor layer exceeds beyond the gate electrode from two opposite directions.

20. The method of manufacturing a TFT driving backplane according to claim 16, wherein the material of the pixel electrode comprises indium-tin oxide.
